(19) United States
(12) Patent Application Publication
(10) Pub. No.: US 2025/0259669 A1
(43) Pub. Date: Aug. 14, 2025

(54) EMBEDDED DYNAMIC MEMORY, IMPLEMENTATION METHOD OF EMBEDDED DYNAMIC MEMORY, AND INTEGRATED CIRCUIT

(71) Applicant: GALAXYCORE SHANGHAI LIMITED CORPORATION, Shanghai (CN)

(72) Inventors: Zixuan ZHAO, Shanghai (CN); Di XU, Shanghai (CN)

(73) Assignee: GALAXYCORE SHANGHAI LIMITED CORPORATION, Shanghai (CN)

(21) Appl. No.: 19/115,730

(22) PCT Filed: Sep. 15, 2023
(86) PCT No.: PCT/CN2023/119103

§ 371 Date: Mar. 26, 2025

(30) Foreign Application Priority Data
Aug. 21, 2023 (CN) 202311055999.5

(51) Int. Cl. G11C 11/4096; G11C 11/4091

(52) U.S. Cl. CPC G11C 11/4096; G11C 11/4091

(57) ABSTRACT

An embedded dynamic memory and an implementation method thereof, and an integrated circuit are provided. The memory includes at least one bank each of which comprises at least one sub-bank; each of the at least one sub-bank comprises a storage cell array and a group of sense amplifiers, each sense amplifier including an independent read control unit and an independent write control unit; and control of various operation modes of the memory is achieved through the read control unit and the write control unit. Embodiments of the present disclosure may achieve parallel reading and writing in the same bank, and parallel reading and writing between different banks.

### CROSS-REFERENCE TO RELATED APPLICATIONS

This application is a National Stage of International Application No. PCT/CN2023/119103 filed on Sep. 15, 2023, which claims priority to Chinese Patent Application No. 202311055999.5, filed on Aug. 21, 2023, and entitled “EMBEDDED DYNAMIC MEMORY, IMPLEMENTATION METHOD OF EMBEDDED DYNAMIC MEMORY, AND INTEGRATED CIRCUIT”, the entire disclosure of which is incorporated herein by reference.

### TECHNICAL FIELD

The present disclosure generally relates to a semiconductor field, and more particularly, to an embedded dynamic memory, an implementation method of an embedded dynamic memory, and an integrated circuit.

### BACKGROUND

Storage data of Random Access Memory (RAM) can be read or written on demand, and a speed of reading and writing is irrelevant with a storage location of the data. This type of memory has a high reading and writing speed, but data stored therein will be lost when power is off. Therefore, the RAM is mainly used to store data used for a short time. According to the different storage information, RAM can be classified into Static RAM (SRAM) and Dynamic RAM (DRAM).

At present, DRAM and a logic circuit are usually manufactured separately on two silicon wafers. For example, for an image sensor, image data thereof needs to be cached in a storage array. An existing practice is usually to manufacture a pixel array, a logic processing circuit and DRAM of the image sensor separately through separate silicon wafers, and then package the three silicon wafers together by stacking.

### SUMMARY

An embodiment of the present disclosure provides a method for implementing an embedded dynamic memory, wherein the memory includes at least one bank each of which includes at least one sub-bank; each of the at least one sub-bank includes a storage cell array and a group of sense amplifiers, each sense amplifier including an independent read control unit and an independent write control unit; and control of various operation modes of the memory is achieved through the read control unit and the write control unit.

In some embodiments, the memory further includes an input/output control module which includes a plurality of read control modules and a plurality of write control modules.

In some embodiments, the plurality of sense amplifiers are coupled to one corresponding independent read control module and one corresponding independent write control module.

In some embodiments, said achieving the control of the various operation modes of the memory through the read control unit and the write control unit includes: enabling a particular bank among a plurality of banks; and configuring internal timing to achieve continuous reading, continuous writing, parallel reading and writing, or interlaced reading and writing of the particular bank.

In some embodiments, said achieving the control of the various operation modes of the memory through the read control unit and the write control unit includes: enabling a particular bank among a plurality of banks in an interlaced manner; and configuring internal timing to achieve continuous reading, continuous writing, or interlaced reading and writing between different banks.

In some embodiments, said achieving the control of the various operation modes of the memory through the read control unit and the write control unit includes: simultaneously enabling at least two banks among a plurality of banks; and configuring internal timing to achieve continuous reading, continuous writing, or interlaced reading and writing of different banks, or parallel reading, parallel writing, or parallel reading and writing of different banks.

In some embodiments, the method includes: reading/writing a first sub-bank of the particular bank in a first time period, and reading/writing a second sub-bank of the particular bank in a second time period, to achieve continuous reading, continuous writing, or interlaced reading and writing of the particular bank; or reading/writing a portion of the first sub-bank in the first time period, and reading/writing another portion of the first sub-bank in the first time period, to achieve parallel reading and writing of the particular bank.

In some embodiments, the method includes: reading/writing a first bank in a first time period, and reading/writing a second bank in a second time period, to achieve continuous reading, continuous writing or interlaced reading and writing of different banks. In some embodiments, the method includes: reading/writing a first bank in a first time period, and reading/writing a second bank in a second time period, to achieve continuous reading, continuous writing or interlaced reading and writing of different banks; or reading/writing the first bank in the first time period, and reading/writing the second bank in the first time period, to achieve parallel reading, parallel writing or parallel reading and writing of different banks.

In some embodiments, the internal timing includes address timing of the plurality of banks, timing of pre-charging units corresponding to different sub-banks of different banks, timing of the read control modules and the write control modules, timing of the read control unit and the write control unit, and timing of an address line of storage cells in the storage cell array.

In some embodiments, the memory includes at least two banks each of which includes at least two sub-banks.

In some embodiments, each sense amplifier further includes an amplifying unit and a pre-charging unit that are coupled to a bit line and a reference bit line; the read control unit includes a first transistor and a second transistor; gates of the first transistor and the second transistor are coupled with each other and coupled to a read control signal; one terminal of the first transistor is coupled to the bit line, and another terminal of the first transistor is coupled to a read control module; one terminal of the second transistor is coupled to the reference bit line, and another terminal of the second transistor is coupled to the readout control module; the write control unit includes a third transistor and a fourth transistor; gates of the third transistor and the fourth transistor are coupled with each other and coupled to a write control signal; one terminal of the third transistor is coupled to the bit line, and another terminal of the third transistor is coupled to a write control module; and one terminal of the fourth transistor is coupled to the reference bit line, and another terminal of the fourth transistor is coupled to the write control module.

An embodiment of the present disclosure provides an embedded dynamic memory including at least one bank each of which includes at least one sub-bank, wherein each of the at least one sub-bank includes a storage cell array and a group of sense amplifier, and each sense amplifier includes an independent read control unit and an independent write control unit.

In some embodiments, the memory further includes an input/output control module which includes a plurality of read control modules and a plurality of write control modules, wherein the plurality of sense amplifiers are coupled to one corresponding independent read control module and one corresponding independent write control module.

In some embodiments, the memory includes at least two banks each of which includes at least two sub-banks.

In some embodiments, each sense amplifier further includes an amplifying unit and a pre-charging unit that are coupled to a bit line and a reference bit line; the read control unit includes a first transistor and a second transistor; gates of the first transistor and the second transistor are coupled with each other and coupled to a read control signal; one terminal of the first transistor is coupled to the bit line, and another terminal of the first transistor is coupled to the read control module; one terminal of the second transistor is coupled to the reference bit line, and another terminal of the second transistor is coupled to the readout control module; the write control unit includes a third transistor and a fourth transistor; gates of the third transistor and the fourth transistor are coupled with each other and coupled to a write control signal; one terminal of the third transistor is coupled to the bit line, and another terminal of the third transistor is coupled to the write control module; and one terminal of the fourth transistor is coupled to the reference bit line, and another terminal of the fourth transistor is coupled to the write control module.

An embodiment of the present disclosure provides an integrated circuit, including the embedded dynamic memory.

Compared with existing dynamic memories, the embedded dynamic memory provided in the present disclosure can achieve parallel reading and writing in the same bank, and parallel reading and writing between different banks.

### BRIEF DESCRIPTION OF THE DRAWINGS

FIG. 1 is a structural diagram of an embedded dynamic memory according to an embodiment of the present disclosure;

FIG. 2 is a structural diagram of a storage cell array of an embedded dynamic memory according to an embodiment of the present disclosure;

FIG. 3 is a structural diagram of a sense amplifier of an embedded dynamic memory according to an embodiment of the present disclosure;

FIG. 4 is a structural diagram in which a plurality of sense amplifiers share an independent readout control line and an independent write control line according to an embodiment of the present disclosure;

FIG. 5 is a structural diagram of an embedded dynamic memory based on FIG. 4;

FIGS. 6 to 12 are timing diagrams in different operation modes according to embodiments of the present disclosure; and

FIG. 13 illustrates an integrated circuit including an embedded dynamic memory according to an embodiment of the present disclosure.

### DETAILED DESCRIPTION

In order to more explicitly describe technical solutions of embodiments of the present disclosure, drawings required for use in the description of the embodiments are introduced briefly below. Obviously, the drawings described below are only some examples or embodiments of the present disclosure. For one skilled in the art, the present disclosure can also be applied to other similar scenarios based on these drawings without creative effort. Unless it is obvious from a language environment or otherwise explained, the same reference numerals in the drawings represent the same structure or operation.

An embodiment of the present disclosure provides a method for implementing an embedded dynamic memory, wherein the memory includes at least one bank each of which comprises at least one sub-bank; each of the at least one sub-bank comprises a storage cell array and a group of sense amplifiers which comprise an independent read control unit and an independent write control unit; and control of various operation modes of the memory is achieved through the read control unit and the write control unit.

Optionally, the memory further includes an input/output control module which includes a plurality of read control modules and a plurality of write control modules. One or a plurality of sense amplifiers are coupled to one corresponding independent read control module and one corresponding independent write control module.

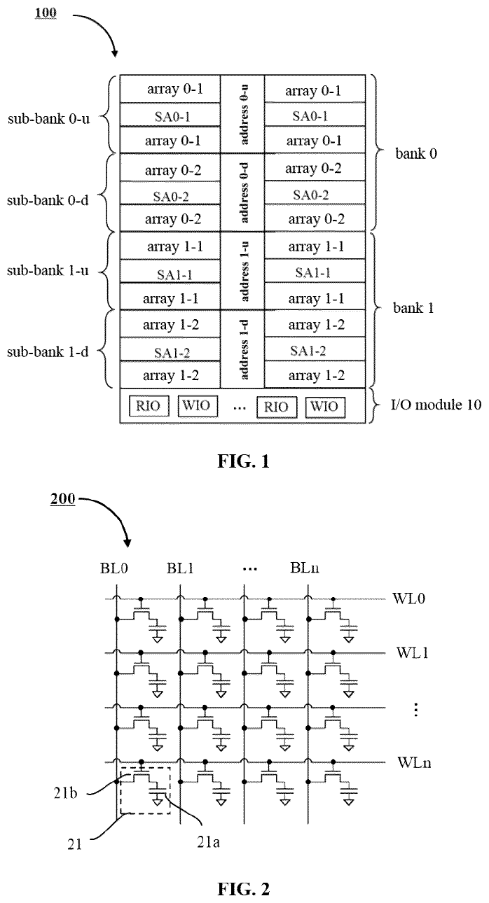

FIG. 1 is a structural diagram of an embedded dynamic memory according to an embodiment of the present disclosure.

The dynamic memory 100 includes a bank 0, a bank 1, and an Input/Output (I/O) module 10. The bank 0 includes a sub-bank 0-u and a sub-bank 0-d. The bank 1 includes a sub-bank 1-u and a sub-bank 1-d.

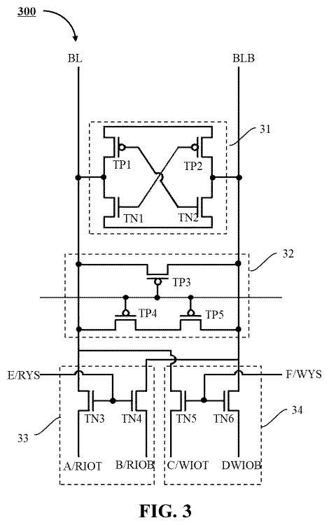

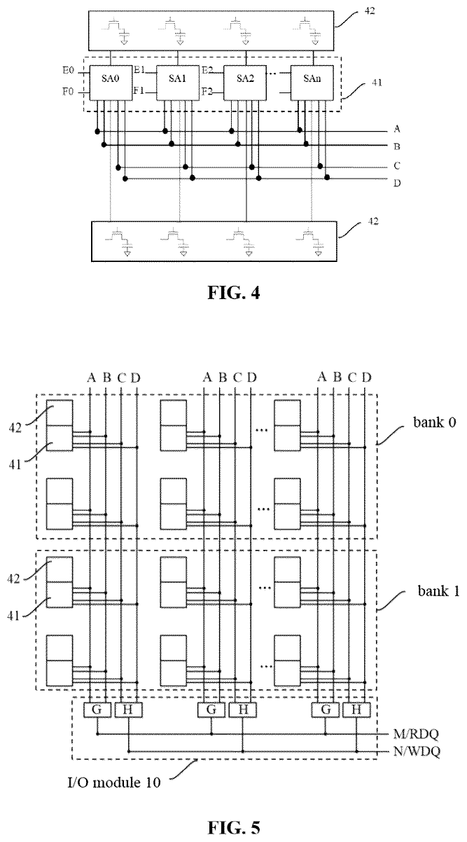

Taking the sub-bank 0-u as an example, the sub-bank 0-u includes arrays 0-1 (also called storage cell array), a Sense Amplifier (SA) 0-1 and an address 0-u. The arrays 0-1 are composed of multiple rows and columns of storage cells. A specific structure of the storage cells can refer to description of FIG. 2. The SA 0-1 includes a plurality of sense amplifiers. A specific structure of the sense amplifier can refer to description of FIG. 3. The address 0-u includes a row address line, a column address line and other related address lines of the storage cells. The arrays 0-1 are distributed in four corners of the sub-bank 0-u. The SA 0-1 is arranged on both sides of the address 0-u and between the two arrays 0-1.

Similarly, the sub-bank 0-d, the sub-bank 1-u and the sub-bank 1-d may have the same structural layout as the sub-bank 0-u. It should be noted that the structural layout of the dynamic memory 100 may also be other designs, which is not limited here. The dynamic memory 100 may include more banks, for example, 3, 4, 5, 6 or 8 banks or more, which is not limited here. Each bank may include more sub-banks, for example, 3, 4, 5, 6 or 8 sub-banks or more, which is not limited here.

FIG. 2 is a structural diagram of a storage cell array of an embedded dynamic memory according to an embodiment of the present disclosure.

The memory cell array 200 includes a plurality of memory cells 21, a plurality of Word Lines (WL) (such as WL1, WL2, . . . , WLn in FIG. 2) and a plurality of Bit Lines (BL) (such as BL1, BL2, . . . , BLn in FIG. 2). The memory cell 21 includes a capacitor 21a and a transistor 21b. One terminal of the capacitor 21a is coupled to a fixed voltage, for example, to the ground (0V), and another terminal of the capacitor 21a is coupled to a source of the transistor 21b. A drain of the transistor 21b is coupled to the bit line. A gate of the transistor 21b is coupled to the word line. The capacitor 21a in the embodiments of the present disclosure may be a deep trench capacitor, and the transistor 21b may be a vertical transfer transistor, thereby reducing an area of a chip.

FIG. 3 is a structural diagram of a sense amplifier of an embedded dynamic memory according to an embodiment of the present disclosure.

Each sense amplifier 300 includes an amplifying unit 31 coupled to a bit line BL and a reference bit line BLB, a pre-charging unit 32, a read control unit 33, and a write control unit 34.

The amplifying unit 31 is composed of a PMOS transistor TP1, a PMOS transistor TP2, an NMOS transistor TN1 and an NMOS transistor TN2. FIG. 3 illustrates their detailed connection relation.

The pre-charging unit 32 is composed of a PMOS transistor TP3, a PMOS transistor TP4 and a PMOS transistor TP5, and gates of the three transistors are connected to a voltage. FIG. 3 also illustrates their detailed connection relation. The pre-charging unit 32 may charge the bit line BL and the reference bit line BLB to a certain voltage value, and then charge or discharge the capacitor 21a in the storage cell 21 when data is read or written.

The read control unit 33 includes an NMOS transistor TN3 and an NMOS transistor TN4. Gates of TN3 and TN4 are coupled to a read control signal line E (or represented as RYS). One terminal of TN3 is coupled to the bit line BL, and another terminal of TN3 is coupled to a read control signal line A (or represented as RIOT). One terminal of TN4 is coupled to the reference bit line BLB, and another terminal of TN4 is coupled to the read control signal line B (or represented as RIOB).

The write control unit 34 includes an NMOS transistor TN5 and an NMOS transistor TN6. Gates of TN5 and TN6 are coupled to a write control signal line F (or represented as WYS).

A terminal of TN5 is coupled to the bit line BL, and another terminal of TN5 is coupled to a write control signal line C (or represented as WIOT). One terminal of TN6 is coupled to the reference bit line BLB, and another terminal of TN6 is coupled to a write control line D (or represented as WIOB).

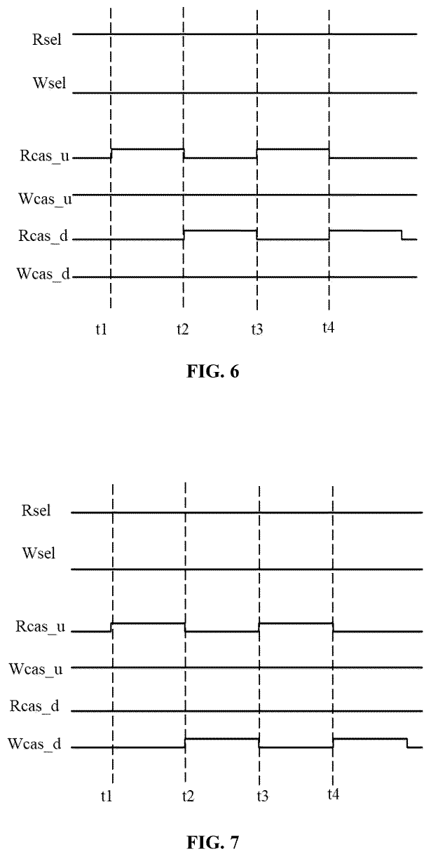

FIG. 4 is a structural diagram in which a plurality of sense amplifiers share an independent readout control line and an independent write control line according to an embodiment of the present disclosure.

As shown in FIG. 4, a group 41 of sense amplifiers is coupled to two corresponding upper and lower memory cell arrays 42. The group 41 of sense amplifier is composed of SA0, SA1, SA2, . . . , SAn. SA0, SA1, SA2, . . . , SAn are commonly coupled to the read control signal line A and the read control signal line B, and are commonly coupled to the write control signal line C and the write control signal line D. Read control signals (such as E0, E1, E2, . . . shown in FIG. 4) corresponding to SA0, SA1, SA2, . . . , SAn and write control signals (such as F0, F1, F2, . . . shown in FIG. 4) corresponding to SA0, SA1, SA2, . . . , SAn are independently controlled.

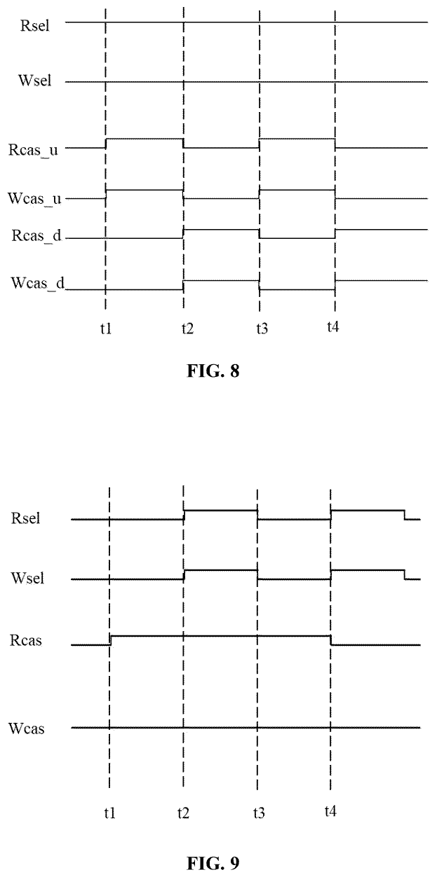

FIG. 5 is a structural diagram of an embedded dynamic memory based on FIG. 4.

As shown in FIG. 5, the dynamic memory is divided into a bank 0 and a bank 1. Each bank includes multiple rows and columns of groups 41 of sense amplifiers and corresponding storage cell arrays 42 (merely one group 41 and one storage cell array 42 are shown in FIG. 5). A plurality of groups 41 of sense amplifiers in a same column are commonly coupled to a corresponding read control module G (or represented as RIO) through the read control signal lines A and B, and are commonly coupled to a corresponding write control module H (or represented as WIO) through the write control signal lines C and D.

Read control modules G and write control modules H, coupled to the plurality of groups 41 of sense amplifiers in different columns, are independent of each other. That is, the I/O module 10 includes a plurality of independent read control modules G and a plurality of independent write control modules H. The plurality of independent read control modules G are commonly coupled to a control terminal M (or represented as RDQ). The plurality of independent write control modules H are commonly coupled to a control terminal N (or represented as WDQ).

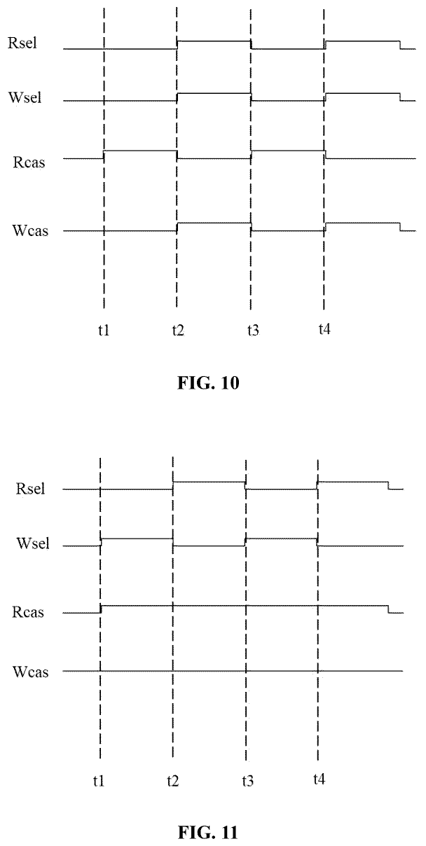

FIGS. 6 to 12 are timing diagrams in different operation modes according to embodiments of the present disclosure.

Rsel and Wsel are used to select a required bank to be enabled. When Rsel and WSel are both low (0), bank 0 is enabled. When Rsel and WSel are both high (1), bank 1 is enabled. When one of Rsel or Wsel is low (0) and the other is high (1), both bank 0 and bank 1 are enabled.

Rcas and Wcas are used to control reading and writing of the bank. Rcas includes Rcas_u and Rcas_d, and Wcas includes Wcas_u and Wcas_d. Each bank includes a sub-bank u and a sub-bank d. Rcas_u represents read control of the sub-bank u. When Rcas_u is high level (1), it indicates reading. Wcas_u represents write control of the sub-bank u. When Wcas_u is high level (1), it indicates writing. Rcas_d represents read control of the sub-bank d. When Rcas_d is high level (1), it indicates reading. Wcas_d represents write control of the sub-bank d. When Wcas_d is high level (1), it indicates writing. It should be noted that timing of some control signals is omitted. For example, timing of the pre-charging units in different sub-banks is not shown in FIGS. 6 to 12, and timing of RIO, WIO, RYS, WYS, etc. is not shown in FIGS. 6 to 12.

In one embodiment, a certain bank among a plurality of banks is enabled and internal timing is configured, to achieve continuous reading, continuous writing, parallel reading and writing, or interlaced reading and writing of the certain bank.

In one embodiment, a certain bank among a plurality of banks is enabled in an interlaced manner and internal timing is configured, to achieve continuous reading, continuous writing, or interlaced reading and writing between different banks.

In one embodiment, at least two banks among a plurality of banks are enabled simultaneously, and internal timing is configured, to achieve continuous reading, continuous writing, interlaced reading and writing of different banks, or parallel reading, parallel writing or parallel reading and writing of different banks. The internal timing includes address timing of the plurality of banks, timing of pre-charging units corresponding to different sub-banks of different banks, timing of the read control modules and the write control modules, timing of the read control unit and the write control unit, and timing of an address line of the storage cells. Detailed description of different read and write modes are provided below in conjunction with relevant drawings.

FIGS. 6, 7, and 8 are timing diagrams of read and write modes in which only one bank (e.g., bank 0) is enabled.

As shown in FIG. 6, the sub-bank 0-u of the bank 0 is read in a first time period (t1 to t2), the sub-bank 0-d of the bank 0 is read in a second time period (t2 to t3), and the sub-bank 0-u of the bank 0 is read in a third time period (t3 to t4), thereby achieving continuous reading of the bank 0.

Similarly, referring to FIG. 6, the sub-bank 0-u of the bank 0 may be written in the first time period (t1 to t2), the sub-bank 0-d of the bank 0 may be written in the second time period (t2 to t3), and the sub-bank 0-u of the bank 0 may be written in the third time period (t3 to t4), thereby achieving continuous writing to the bank 0.

As shown in FIG. 7, the sub-bank 0-u of the bank 0 is read in the first time period (t1 to t2), the sub-bank 0-d of the bank 0 is written in the second time period (t2 to t3), and the sub-bank 0-u of the bank 0 is read in the third time period (t3 to t4), thereby achieving interlaced reading and writing of the bank 0.

As shown in FIG. 8, a portion of the sub-bank 0-u of the bank 0 (e.g., a corresponding upper half of the sub-bank 0-u) is read in the first time period (t1 to t2), another portion of the sub-bank 0-u of the bank 0 (e.g., a corresponding lower half of the sub-bank 0-u) is written in the first time period (t1 to t2), a portion of the sub-bank 0-d of the bank 0 (e.g., a corresponding upper half of the sub-bank 0-d) is written in the second time period (t2 to t3), and another portion of the sub-bank 0-d of the bank 0 (e.g., a corresponding lower half of the sub-bank 0-d) is read in the second time period (t2 to t3), a portion of the sub-bank 0-u of the bank 0 (e.g., the corresponding upper half of the sub-bank 0-u) is read in the third time period (t3 to t4), and another portion of the sub-bank 0-u of the bank 0 (e.g., the corresponding lower half of the sub-bank 0-u) is written in the third time period (t3 to t4), thereby achieving parallel reading and writing of the bank 0.

FIG. 9 and FIG. 10 are timing diagrams of read and write modes in which one of two banks (bank 0 and bank 1) is enabled in an interlaced manner. Rcas represents the read control of the bank. When Rcas is at a high level (1), it represents reading. Wcas represents the write control of the bank. When Wcas is at a high level (1), it represents writing.

As shown in FIG. 9, the bank 0 is read in the first time period (t1 to t2), the bank 1 is read in the second time period (t2 to t3), and the bank 0 is read in the third time period (t3 to t4), thereby achieving continuous reading of different banks.

Similarly, referring to FIG. 9, the bank 0 is written in the first time period (t1 to t2), the bank 1 is written in the second time period (t2 to t3), and the bank 0 is written in the third time period (t3 to t4), thereby achieving continuous writing of different banks.

As shown in FIG. 10, the bank 0 is read in the first time period (t1 to t2), the bank 1 is written in the second time period (t2 to t3), and the bank 0 is read in the third time period (t3 to t4), thereby achieving interlaced reading and writing of different banks.

FIG. 11 and FIG. 12 are timing diagrams of read and write modes in which two banks (bank 0 and bank 1) are simultaneously enabled. Rcas represents read control of the bank. When Rcas is at a high level (1), it represents reading. Wcas represents write control of the bank. When Wcas is at a high level (1), it represents writing.

As shown in FIG. 11, by controlling Rsel, Wsel, Rcas and Wcas, the bank 0 is read in the first time period (t1 to t2), the bank 1 is read in the first time period (t1 to t2), the bank 0 is read in the second time period (t2 to t3), the bank 1 is read in the second time period (t2 to t3), the bank 0 is read in the third time period (t3 to t4), and the bank 1 is read in the third time period (t3 to t4), thereby achieving parallel reading of different banks. Similarly, parallel writing, and interlaced reading and writing of different banks can also be achieved.

As shown in FIG. 12, by controlling Rsel, Wsel, Rcas and Wcas, the bank 0 is read in the first time period (t1 to t2), the bank 1 is written in the first time period (t1 to t2), the bank 0 is written in the second time period (t2 to t3), the bank 1 is read in the second time period (t2 to t3), the bank 0 is read in the third time period (t3 to t4), and the bank 1 is written in the third time period (t3 to t4), thereby achieving parallel reading and writing of different banks and continuous reading and writing between different banks.

It should be noted that alternatively, the read and write modes of the embedded memory in the embodiments of the present disclosure may be implemented by changing the timing of different control signals, which is not limited here.

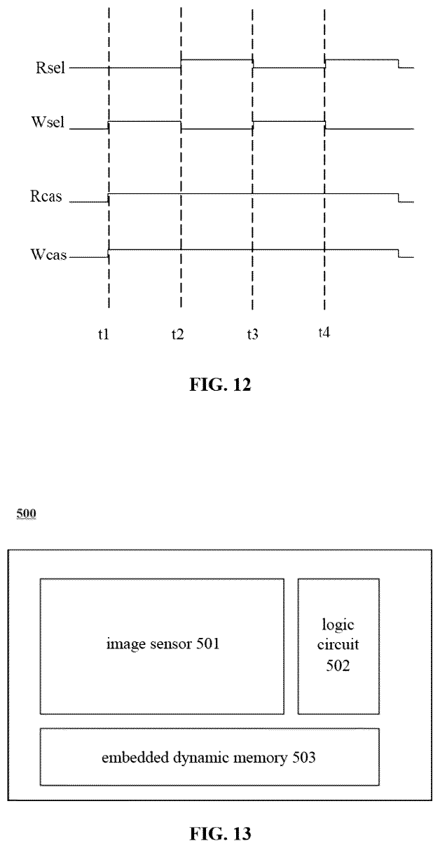

FIG. 13 illustrates an integrated circuit including an embedded dynamic memory according to an embodiment of the present disclosure.

The integrated circuit 500 includes an image sensor 501, a logic circuit 502, and an embedded dynamic memory 503. The embedded dynamic memory 503 may be configured to store image data of the image sensor 501.

Basic concepts have been described above. Obviously, for those skilled in the art, the above detailed disclosure is only for example and does not limit the present disclosure. Although not explicitly stated herein, those skilled in the art may make various modifications, improvement and corrections to the present disclosure. Such modifications, improvement and corrections are suggested in the present disclosure, thus, such modifications, improvement and corrections still belong to the spirit and scope of the exemplary embodiments of the present disclosure.

It should be understood that the embodiments in the present disclosure are only used to illustrate principles of the embodiments of the present disclosure. Other variations may also fall within the scope of the present disclosure. Therefore, as examples and not limitations, alternative configurations of the embodiments of the present disclosure may be considered consistent with teachings of the present disclosure. Accordingly, the embodiments of the present disclosure are not limited to the embodiments explicitly introduced and described in the present disclosure.

What is claimed is:

1. A method for implementing an embedded dynamic memory, wherein
the memory comprises at least one bank each of which comprises at least one sub-bank;
each of the at least one sub-bank comprises a storage cell array and a group of sense amplifiers, each sense amplifier comprising an independent read control unit and an independent write control unit; and
control of various operation modes of the memory is achieved through the read control unit and the write control unit.

2. The method according to claim 1, wherein the memory further comprises an input/output control module which comprises a plurality of read control modules and a plurality of write control modules.

3. The method according to claim 2, wherein the plurality of sense amplifiers are coupled to one corresponding independent read control module and one corresponding independent write control module.

4. The method according to claim 3, wherein said achieving the control of the various operation modes of the memory through the read control unit and the write control unit comprises:
enabling a particular bank among a plurality of banks; and
configuring internal timing to achieve continuous reading, continuous writing, parallel reading and writing, or interlaced reading and writing of the particular bank.

5. The method according to claim 3, wherein said achieving the control of the various operation modes of the memory through the read control unit and the write control unit comprises:
enabling a particular bank among a plurality of banks in an interlaced manner; and
configuring internal timing to achieve continuous reading, continuous writing, or interlaced reading and writing between different banks.

6. The method according to claim 3, wherein said achieving the control of the various operation modes of the memory through the read control unit and the write control unit comprises:
simultaneously enabling at least two banks among a plurality of banks; and
configuring internal timing to achieve continuous reading, continuous writing, or interlaced reading and writing of different banks, or parallel reading, parallel writing, or parallel reading and writing of different banks.

7. The method according to claim 4, comprising:
reading/writing a first sub-bank of the particular bank in a first time period, and reading/writing a second sub-bank of the particular bank in a second time period, to achieve continuous reading, continuous writing, or interlaced reading and writing of the particular bank; or
reading/writing a portion of the first sub-bank in the first time period, and reading/writing another portion of the first sub-bank in the first time period, to achieve parallel reading and writing of the particular bank.

8. The method according to claim 5, comprising:
reading/writing a first bank in a first time period, and reading/writing a second bank in a second time period, to achieve continuous reading, continuous writing or interlaced reading and writing of different banks.

9. The method according to claim 6, comprising:
reading/writing a first bank in a first time period, and reading/writing a second bank in a second time period, to achieve continuous reading, continuous writing or interlaced reading and writing of different banks; or
reading/writing the first bank in the first time period, and reading/writing the second bank in the first time period, to achieve parallel reading, parallel writing or parallel reading and writing of different banks.

10. The method according to claim 4, wherein the internal timing comprises address timing of the plurality of banks, timing of pre-charging units corresponding to different sub-banks of different banks, timing of the read control modules and the write control modules, timing of the read control unit and the write control unit, and timing of an address line of storage cells in the storage cell array.

11. The method according to claim 1, wherein the memory comprises at least two banks each of which comprises at least two sub-banks.

12. The method according to claim 1, wherein
each sense amplifier further comprises an amplifying unit and a pre-charging unit that are coupled to a bit line and a reference bit line;
the read control unit comprises a first transistor and a second transistor;
gates of the first transistor and the second transistor are coupled with each other and coupled to a read control signal;
one terminal of the first transistor is coupled to the bit line, and another terminal of the first transistor is coupled to a read control module;
one terminal of the second transistor is coupled to the reference bit line, and another terminal of the second transistor is coupled to the readout control module;
the write control unit comprises a third transistor and a fourth transistor;
gates of the third transistor and the fourth transistor are coupled with each other and coupled to a write control signal;
one terminal of the third transistor is coupled to the bit line, and another terminal of the third transistor is coupled to a write control module; and
one terminal of the fourth transistor is coupled to the reference bit line, and another terminal of the fourth transistor is coupled to the write control module.

13. An embedded dynamic memory, comprising:
at least one bank each of which comprises at least one sub-bank;
wherein each of the at least one sub-bank comprises a storage cell array and a group of sense amplifiers, and each sense amplifier comprises an independent read control unit and an independent write control unit.

14. The embedded dynamic memory according to claim 13, further comprising an input/output control module which comprises a plurality of read control modules and a plurality of write control modules, wherein the plurality of sense amplifiers are coupled to one corresponding independent read control module and one corresponding independent write control module.

15. The embedded dynamic memory according to claim 14, comprising at least two banks each of which comprises at least two sub-banks.

16. The embedded dynamic memory according to claim 15, wherein each sense amplifier further comprises an amplifying unit and a pre-charging unit that are coupled to a bit line and a reference bit line;
the read control unit comprises a first transistor and a second transistor;
gates of the first transistor and the second transistor are coupled with each other and coupled to a read control signal;
one terminal of the first transistor is coupled to the bit line, and another terminal of the first transistor is coupled to the read control module;
one terminal of the second transistor is coupled to the reference bit line, and another terminal of the second transistor is coupled to the readout control module;
the write control unit comprises a third transistor and a fourth transistor;
gates of the third transistor and the fourth transistor are coupled with each other and coupled to a write control signal;
one terminal of the third transistor is coupled to the bit line, and another terminal of the third transistor is coupled to the write control module; and
one terminal of the fourth transistor is coupled to the reference bit line, and another terminal of the fourth transistor is coupled to the write control module.

17. An integrated circuit, comprising an embedded dynamic memory, wherein the embedded dynamic memory comprises:
at least one bank each of which comprises at least one sub-bank;
wherein each of the at least one sub-bank comprises a storage cell array and a group of sense amplifiers, and each sense amplifier comprises an independent read control unit and an independent write control unit.

18. The method according to claim 5, wherein the internal timing comprises address timing of the plurality of banks, timing of pre-charging units corresponding to different sub-banks of different banks, timing of the read control modules and the write control modules, timing of the read control unit and the write control unit, and timing of an address line of storage cells in the storage cell array.

19. The method according to claim 6, wherein the internal timing comprises address timing of the plurality of banks, timing of pre-charging units corresponding to different sub-banks of different banks, timing of the read control modules and the write control modules, timing of the read control unit and the write control unit, and timing of an address line of storage cells in the storage cell array.
